(19) United States
(12) Patent Application Publication
(10) Pub. No.: US 2019/0377100 A1
(43) Pub. Date: Dec. 12, 2019

(54) METAL DETECTOR FOR BURIED AND CORRODED PIPELINE

(71) Applicant: Tsinghua University, Beijing (CN)

(72) Inventors: XIAO-PING ZHENG, Beijing (CN); YE-QING YANG, Beijing (CN); HUA GENG, Beijing (CN)

(73) Assignee: Tsinghua University, Beijing (CN)

(21) Appl. No.: 16/233,122

(22) Filed: Dec. 27, 2018

Related U.S. Application Data
(63) Continuation of application No. PCT/CN2018/075038, filed on Feb. 2, 2018.

(30) Foreign Application Priority Data
Dec. 29, 2017 (CN) 201711483216.8

(51) Int. Cl. G01V 3/165; H03F 3/45; H03F 1/34

(52) U.S. Cl. CPC G01V 3/165; H03F 3/45071; H03F 1/34; H03F 2203/45528; H03B 5/32; H03F 2200/141; H03F 2200/129; H03F 2203/45116; H03F 2203/45526; H03F 2200/534

(57) ABSTRACT

A metal detector for buried and corroded pipeline is provided, comprising: a transmitting coil configured to transmit a detection signal to a pipeline; a frequency selection unit electrically connected to the transmitting coil for regulating a frequency of the detection signal; two receiving coils respectively and symmetrically disposed at two opposite sides of the transmitting coil for respectively receiving a reflected signal returned from the pipeline; an analog-digital conversion unit respectively and electrically connected to the two receiving coils for converting the reflected signal into a digital signal; and a control unit electrically connected to the analog-digital conversion unit. In the present disclosure, by comparing intensities of the reflected signals received by the two receiving coils, it can be efficiently and accurately determined whether corrosion has occurred to the pipeline.

### CROSS-REFERENCE TO RELATED APPLICATIONS

This application claims all benefits accruing under 35 U.S.C. § 119 from China Patent Application No. 201711483216.8, filed on Dec. 29, 2017 in the State Intellectual Property Office of China, the content of which is hereby incorporated by reference. This application is a continuation under 35 U.S.C. § 120 of international patent application PCT/CN2018/075038 filed on Feb. 2, 2018, the content of which is also hereby incorporated by reference.

### FIELD

The present disclosure relates to detection of materials, in particular to a metal detector for buried and corroded pipeline.

### BACKGROUND

Underground pipe network is an important infrastructure for improving people's living. However, buried pipelines are susceptible to corrosion especially over a long period of time. Although the locations of the buried pipelines are generally well recorded, it is difficult to identify whether the buried pipelines are corroded until they are exposed.

### SUMMARY

A metal detector for buried and abandoned chemical weapons of Japan is provided.

The metal detector includes a transmitting coil configured to transmit a detection signal to a pipeline, a frequency selection unit electrically connected to the transmitting coil for regulating a frequency of the detection signal, two receiving coils respectively and symmetrically disposed at two opposite sides of the transmitting coil for respectively receiving a reflected signal returned from the pipeline, an analog-digital conversion unit respectively and electrically connected to the two receiving coils for converting the reflected signal into a digital signal, and a control unit electrically connected to the analog-digital conversion unit.

In one embodiment, the transmitting coil and the two receiving coils are located in a same plane.

In one embodiment, the two receiving coils are circular, and an outer diameter of each of the two receiving coils is equal to or smaller than a diameter of the pipeline.

In one embodiment, the frequency selection unit includes an operational amplifier, a first amplifying circuit including a resistor R4, two ends of the resistor R4 being respectively and electrically connected to an inverting input of the operational amplifier and an output of the operational amplifier, a resistor R1, one end of the resistor R1 being grounded and the other end of the resistor R1 being electrically connected to the inverting input of the operational amplifier, and a frequency selection circuit including a variable capacitor C1 and a variable resistor R2, one end of the variable capacitor C1 being electrically connected to one end of the variable resistor R2 and grounded, and the other end of variable capacitor C1 and the other end of the variable resistor R2 being electrically connected to a non-inverting input of the operational amplifier, and a variable capacitor C2 and a variable resistor R3 being electrically connected in series between the inverting input of the operational amplifier and the output of the operational amplifier.

In one embodiment, the frequency selection unit further includes a stabilivolt Dz configured to control an amplitude of a feedback voltage of the operational amplifier, the stabilivolt Dz is electrically connected between the inverting input of the operational amplifier and the output of the operational amplifier.

In one embodiment, the metal detector further includes a second amplifying circuit electrically connected between the frequency selection unit and the transmitting circuit, wherein the second amplifying circuit includes a first step-up transformer including a first primary coil electrically connected to the frequency selection unit, a first secondary coil and a second secondary coil being electrically connected in series, a second step-up transformer including a second primary coil and a third primary coil being electrically connected in series, a third secondary coil, a first transistor, one end of the first secondary coil being electrically connected to a base of the first transistor, the other end of the first secondary coil being grounded, an emitter of the first transistor being grounded, a collector of the first transistor being electrically connected to one end of the second primary coil, and the other end of the second primary coil being electrically connected to a cathode of a power supply V1, and a second transistor, one end of the second secondary coil being electrically connected to a base of the second transistor, the other end of the second secondary coil being grounded, an emitter of the second transistor being grounded, a collector of the second transistor being electrically connected to one end of the third primary coil, and the other end of the third primary coil is electrically connected to the cathode of the power supply V1.

In one embodiment, the metal detector further includes a human-machine interaction module including a display unit and an input unit respectively and electrically connected to the control unit.

In one embodiment, the metal detector further includes a power supply unit respectively and electrically connected to the control unit, the analog-digital conversion unit, and the frequency selection unit.

In one embodiment, the metal detector further includes a voltage stabilizing circuit electrically connected to an output of the power supply unit and further respectively and electrically connected to the control unit, the analog-digital conversion unit, and the frequency selection unit, wherein the voltage stabilizing circuit includes a resistor R19 and a stabilivolt D1, the resistor R19, the stabilivolt D1, and the power supply unit being electrically connected in series, and the stabilivolt D1 being electrically connected in parallel with the control unit.

In one embodiment, the metal detector further includes a third amplifying circuit electrically connected between each of the two receiving coils and the analog-digital conversion unit.

In the present disclosure, by comparing intensities of the reflected signals received by the two receiving coils, it can be efficiently and accurately determined whether corrosion has occurred to the pipeline.

### BRIEF DESCRIPTION OF THE DRAWINGS

FIG. 1 is a schematic diagram of an operating principle of one embodiment of a metal detector for buried and corroded pipeline.

FIG. 2 is a system diagram of the metal detector.

FIG. 3 is a circuit diagram of one embodiment of a frequency selection unit.

FIG. 4 is a diagram of one embodiment of an amplifying circuit at a transmitting end of the metal detector.

FIG. 5 is a diagram of one embodiment of a voltage stabilizing circuit.

FIG. 6 is a schematic diagram of one embodiment of a digital signal processor.

FIG. 7 is a diagram of one embodiment of a reset circuit.

FIG. 8 is a diagram of one embodiment of a crystal oscillation circuit.

FIG. 9 is a schematic diagram of one embodiment of an external RAM.

### DETAILED DESCRIPTION

For a clear understanding of the technical features, objects and effects of the present disclosure, specific embodiments of the present disclosure will now be described in detail with reference to the accompanying drawings. It is to be understood that the following description is merely exemplary embodiments of the present disclosure, and is not intended to limit the scope of the present disclosure.

A buried pipeline can be corroded by chemical and/or electrochemical reactions with its environment, which consequently changed the original chemical, mechanical, and physical performances thereof. For example, a rusting of a metal, a well-known example of the corrosion, can enable the mechanical properties such as plasticity, strength, and tenacity of the buried pipeline to decrease significantly. In addition, on account of different reaction mechanisms and reaction environments, the corrosion of the buried pipeline can be classified into general corrosion, pitting corrosion, crevice corrosion, intergranular corrosion, and filiform corrosion.

The general corrosion, also known as uniform corrosion, behaves as uniform thinning of the entire pipeline due to substantially the same rate of corrosion.

The pitting corrosion is a kind of extremely localized corrosion that leads to forming holes in the pipeline due to non-uniform density of the pipeline. The resultant holes are usually small and deep.

The crevice corrosion refers to corrosion occurring in confined spaces such as contact areas between parts of the pipeline and welds of the pipeline. A crevice with a width of 0.025 mm to 0.1 mm is more susceptible to cause corrosion because a concentration cell is more easily formed within the above width range. If the crevice is too narrow, substances causing the corrosion cannot enter into the crevice. However, if the crevice is a little wider, the substances causing the corrosion would pass through the crevice.

The intergranular corrosion is a form of corrosion where the boundaries of crystallites of the material are more susceptible to corrosion than their interiors. The intergranular corrosion proceeds along the boundaries of grains in the metal or near the boundaries with the largest portion of the grain remaining unaffected, thereby forming a localized corrosion. The main reason causing the intergranular corrosion is that the texture and structure of the boundary is different from the inside of the grain and consequently their electrochemical properties are different. The intergranular corrosion can lead to significant decrease of the plasticity, the strength, and the tenacity of metal materials.

The filiform corrosion is a thread-like type of corrosion which develops under protective coatings on the metal of the pipeline. When salt compound, such as chloride, is contained in the protective coating, water can be absorbed by the protective coatings and then penetrate the protective coatings to form droplet. Because the droplet contains more oxygen at its edge region than center region, a galvanic corrosion is created between the edge region and the center region driven by a differential aeration cell. Consequently, hydroxyl ions are generated at the edge region, which decreases the surface tension of the droplet and facilitates the flow of the droplet, thereby forming the filiform corrosion.

Due to the corrosion, the metal contained in the pipeline has been converted to rust. Components of the rust are complicated and can vary under different circumstances, mainly are metallic oxides such as Fe₂O₃, FeOOH, FeO, Fe(OH)₂, and Fe₃O₄. In the present disclosure, a metal detector 10 is provided to detect the buried pipeline by detecting ferromagnetic substance such as ferric oxide and ferroferric oxide. Magnetized ferric oxide and magnetized ferroferric oxide are less magnetic than magnetized iron.

According to Lenz's law, when a conductor moves cutting magnetic induction lines, eddy current is produced inside the conductor, and a direction of magnetic field generated by the eddy current is opposite to a direction of magnetic field generated by original transmitting circuit, so that a current intensity and a current phase of the transmitting circuit are changed, which further affects an equivalent impedance of a receiving circuit. The equivalent impedance can be further resolved into an equivalent resistor and an equivalent inductance. When the conductor is passing through the transmitting magnetic field, the equivalent resistor of the receiving circuit is increased and the equivalent inductance of the receiving circuit is changed according to a magnetism of the conductor, more specifically, if the conductor is magnetic, the receiving circuit is increased and if the conductor is non-magnetic, the receiving circuit is decreased. In addition, substances with different permeabilities will have different magnetic phases. It is found that as a substance goes deeper underground, the magnetic phase of the substance is not obviously changed, meanwhile, the magnetic phase of the substance is also not changed with the size and orientation of the substance. Therefore, a kind of the substance can be decided by detecting and calculating the phase of the equivalent impedance, while the depth of the substance buried and the size of the substance can be decided by detecting and calculating the amplitude of the equivalent impedance.

With regard to the metal detector 10, the detection performance is affected by a current frequency of the transmitting coil. More specifically, if the current frequency is relatively low, the electromagnetic wave transmitted would have better penetrability and thus could go deeper underground. However, it may fail to detect a small target. If the current frequency is relatively high, the small target would be detected successfully, but the detection range would not be wide. In addition, each substance corresponds to an optimum detection frequency, that is, the substance is more easily to be found at the optimum detection frequency. The optimum detection frequency is mainly affected by a ferromagnetism intensity of the substance detected. In general, metal (such as iron) corresponds to a relatively low optimum detection frequency and a ferromagnetic substance, such as rust, corresponds to a relatively high optimum detection frequency. In the present disclosure, a transmitting frequency of the metal detector 10 can be in a range from about 20 kHz to about 80 kHz.

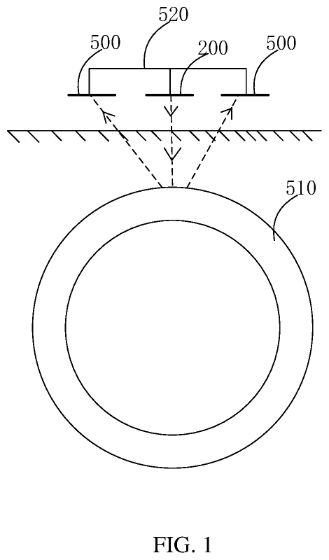

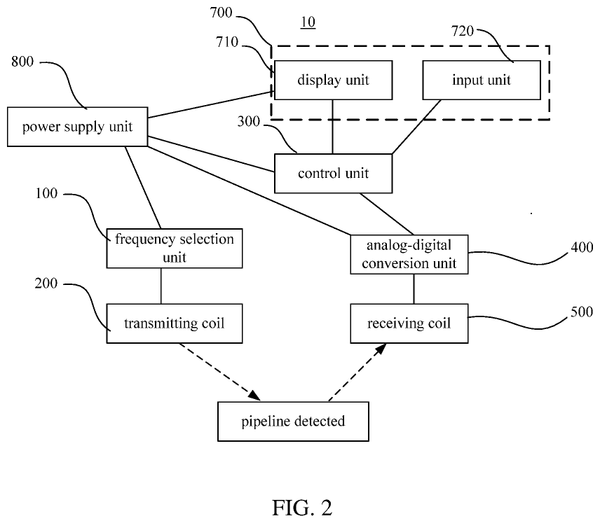

Referring to FIG. 1 and FIG. 2, one embodiment of the metal detector 10 includes a frequency selection unit 100, a transmitting coil 200, two receiving coils 500, an analog-digital conversion unit 400, and a control unit 300. The transmitting coil 200 is configured to transmit a detection signal to a pipeline 510. The frequency selection unit 100 can be electrically connected to the transmitting coil 200 to regulate a frequency of the detection signal. The two receiving coils 500 can be respectively and symmetrically disposed at two opposite sides of the transmitting coil 200 to respectively receive a reflected signal returned from the pipeline 510. The analog-digital conversion unit 400 can be respectively and electrically connected to the two receiving coils 500 for converting analog signals into digital signals. The control unit 300 can be electrically connected to the analog-digital conversion unit 400 for processing and displaying the reflected signal. The frequency selection unit 100 can be configured to regulate the frequency of the detection signal by regulating a current frequency of the transmitting coil 200.

The transmitting coil 200 and/or the receiving coil 500 can be respectively a planar coil. A vertical line of the transmitting coil 200 can be parallel to that of the receiving coil 500. In one embodiment, the transmitting coil 200 and the two receiving coils 500 can be located in the same plane, which not only facilitates the miniaturization of the metal detector 10, but minimizes the mutual interference with each other. The transmitting coil 200 and the two receiving coils 500 can be fixed on a frame 520.

The transmitting coil 200 and the receiving coil 500 can be independently made by metal materials. A shape of the transmitting coil 200 or the receiving coil 500 is not limited, such as can be a rectangle or a circle, as long as it is convenient to transmit or receive signal. In one embodiment, shapes of the transmitting coil 200 and the receiving coil 500 can be respectively a circle. The transmitting coil 200 and the receiving coil 500 both can be made of copper. In one embodiment, a wire of the transmitting coil 200 and/or a wire of the receiving coil 500 can be protected by an insulating material, for example, the insulating material can be coated on a surface of the wire.

To detect the pipeline 510, a location of the pipeline 510 can be firstly determined according to records. The metal detector 10 can be positioned such that the transmitting coil 200 and the two receiving coils 500 are both parallel to a horizontal plane (which generally is parallel to an axis of the pipeline 510) and the two receiving coils 500 are symmetric about the axis of the pipeline 510, so that there would be two portions symmetric about both the transmitting coil 200 and the axis of the pipeline 510 provided on a surface of the pipeline 510 to reflect the detection signal. If the reflected signals respectively received by the two receiving coils 500 are different, for example, has different intensities or phases, it can be determined that localized corrosion is occurred to the pipeline 510. If at least one of the reflected signals respectively received by the two receiving coils 500 is distinctly different with a normal reflected signal, it can be determined that corrosion has occurred to the pipeline 510. An entire length of the pipeline 510 can be detected by moving the metal detector 10 along the axis of the pipeline 510. By comparing intensities of the reflected signals received by the two receiving coils 500, it can be efficiently and accurately determined whether corrosion has occurred to the pipeline.

In one embodiment, the receiving coil 500 is circular. An outer diameter of the receiving coil 500 can be equal to or smaller than a diameter of the pipeline 510, so that projections of centers of the two receiving coils 500 and the transmitting coil 200 on a horizontal plane can be located within a projection of the pipeline 510 on the horizontal plane. In this way, signal attenuation during detection can be reduced and the accuracy of the detection is increased.

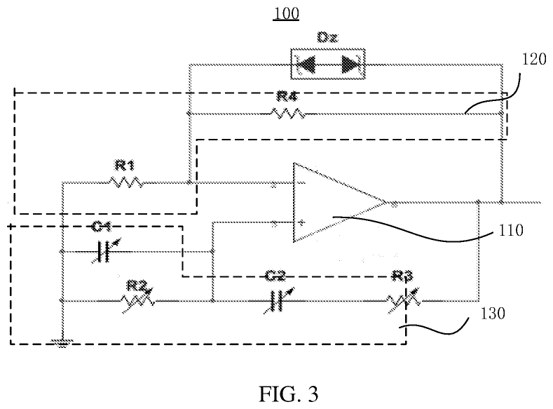

Referring to FIG. 3, in one embodiment, the frequency selection unit 100 can further include an operational amplifier 110, a first amplifying circuit 120, and a frequency selection circuit 130. The first amplifying circuit 120 can include a resistor R4. Two ends of the resistor R4 can be respectively and electrically connected to an inverting input and an output of the operational amplifier 110. The first amplifying circuit 120 can further include a variable resistor R1. One end of the variable resistor R1 can be grounded, and the other end of the variable resistor R1 can be electrically connected to the inverting input of the operational amplifier 110.

The frequency selection circuit 130 can include a variable capacitor C1, a variable resistor R2, a variable capacitor C2, and a variable resistor R3. One end of the variable capacitor C1 and one end of the variable resistor R2 can be electrically connected to each other and grounded. The other end of the variable capacitor C1 and the other end of the variable resistor R2 can be respectively and electrically connected to a non-inverting input of the operational amplifier 110. The variable capacitor C2 and the variable resistor R3 can be electrically connected in series with each other between the inverting input of the operational amplifier 110 and the output of the operational amplifier 110. The frequency selection circuit 130 is configured to change the frequency of the detection signal. The first amplifying circuit 120 and the frequency selection circuit 130 cooperate to perform amplification by using positive feedback mechanism, wherein a feedback factor F is equal to a ratio of a voltage of the non-inverting input of the operational amplifier 110 to a voltage of the output of the operational amplifier 110. More specifically, the feedback factor F can be calculated by the following equation:

$$F = \frac{k * k}{k * k + 2 + j ( wRC - \frac{1}{wRC} )} .$$

wherein k is a real number, R=R2=R3, and C=C1=C2. As can be seen from the above equation, if

$$\frac{1}{wC} > R or \frac{1}{wC} < R ,$$

and an amplification factor of the first amplifying circuit 120 is slightly more than (k*k+2)/(k*k), then a sinusoidal wave with a frequency satisfying

$$f = \frac{1}{2 π RC}$$

can be separated out. Moreover, since the amplification factor is less than 1, other frequency components will be attenuated to 0, and consequently the sinusoidal wave can be isolated.

To ensure that the amplification factor of the first amplifying circuit 120 is slightly more than (k*k+2)/(k*k), and R4/R1 is required to be slightly more than 2. It can be seen form equation

$$f = \frac{1}{2 π RC}$$

that a frequency of the sinusoidal wave output from the frequency selection unit 100 can be regulated by changing values of R and C, namely by changing the values of the variable resistors R2 and R3 and/or the values of the variable capacitances C1 and C2. In one embodiment, by using a switch and variable capacitances having wide capacitance ranges, the frequency of the sinusoidal wave can be coarsely regulated. In addition, by using a digital potentiometer to adjust resistor values of variable resistors, the frequency of the sinusoidal wave can be finely regulated.

In one embodiment, the frequency selection unit 100 can further includes a stabilivolt Dz configured to control an amplitude of a feedback voltage of the operational amplifier 110. The stabilivolt Dz can be electrically connected between the inverting input of the operational amplifier 110 and the output of the operational amplifier 110. Since the first amplifying circuit 120 performs amplification by using positive feedback mechanism, an output voltage should be limited such as by the stabilivolt Dz.

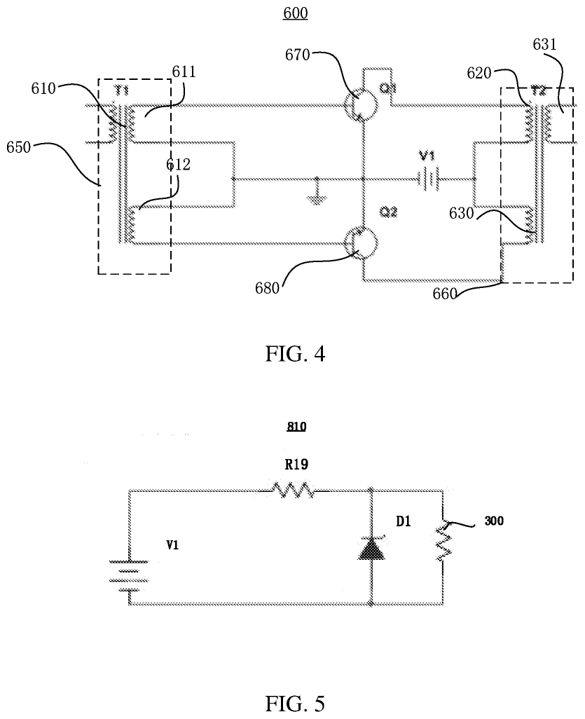

Referring to FIG. 4, in one embodiment, the metal detector 10 can further include a second amplifying circuit 600 electrically connected between the frequency selection unit 100 and the transmitting circuit 200. The second amplifying circuit 600 can include a first step-up transformer 650, a second step-up transformer 660, a first transistor 670, and a second transistor 680. The first step-up transformer 650 can include a first primary coil 610, a first secondary coil 611, and a second secondary coil 612. The first primary coil 610 can be electrically connected to the frequency selection unit 100. The first secondary coil 611 and the second secondary coil 612 can be electrically connected in series. The second step-up transformer 660 can include a second primary coil 620, a third primary coil 630, and a third secondary coil 631. The second primary coil 620 and the third primary coil 630 can be electrically connected in series. One end of the first secondary coil 611 can be electrically connected to a base of the first transistor 670 and the other end of the first secondary coil 611 can be grounded. An emitter of the first transistor 670 can be grounded. A collector of the first transistor 670 can be electrically connected to one end of the second original coil 620, and the other end of the second original coil 620 can be electrically connected to a cathode of a power source V1. One end of the second secondary coil 612 can be electrically connected to a base of the second transistor 680, and the other end of the second secondary coil 612 can be grounded. An emitter of the second transistor 680 can be grounded. A collector of the second transistor 680 can be electrically connected to one end of the third primary coil 630, and the other end of the third primary coil 630 can be electrically connected to an anode of the power supply V1. The second amplifying circuit 600 can be a push-pull amplifying circuit. In one embodiment, the signal input from the frequency selection unit 100 to the first step-up transformer 650 is such that when the polarity of the voltage of the first step-up transformer 650 is positive/negative, the first transistor 670 is turned on and the second transistor 680 is turned off, when the polarity of the voltage of the first step-up transformer 650 is negative/positive, the first transistor 670 is turned off and the second transistor 680 is turned on.

The first step-up transformer 650 is configured to increase the voltage output by the frequency selection unit 100. The second step-up transformer 660 is configured to increase the primary equivalent resistor of the load to improve the power consumption efficiency and reduce the power loss caused by the small resistor of the transmitting coil 200.

In one embodiment, the metal detector 10 can further include a human-machine interaction module 700. The human-machine interaction module 700 can include a display unit 710 and an input unit 720. The display unit 710 and the input unit 720 can be respectively and electrically connected to the control unit 300. The display unit 710 is configured to display a detection result. The display unit 710 can include a liquid crystal display. The detection result displayed can include a kind and an orientation of the substance detected. In addition, information such as a current transmitting frequency and a frequency and a phase of the received signal can further be displayed by the display unit 710. In one embodiment, the liquid crystal display is a 128×64 dot matrix liquid crystal display (LCD 12864). The LCD 12864 is easy to use and inexpensive and has a simpler circuit structure and software program design compared to other dot matrix display module. The specific parameters of the LCD 12864 are listed as follows.

| 1 | power supply voltage | 3.3 V |
|---|---|---|
| 2 | display resolution | 128 × 64 |
| 3 | built-in font file | providing 8192 bitmap fonts |
| 4 | built-in 128 16 × 8 dot characters | |
| 5 | clock frequency | 2 MHz |
| 6 | display mode | STN, transflective, positive |
| 7 | driving method | 1/33 DUTY, ⅙ BIAS |
| 8 | viewing direction | 6 o'clock |
| 9 | communication mode | optionally, serial prot, parallel port |
| 10 | built-in DC-DC switching circuit without additional negative voltage | |
| 11 | without chip selection signal, simplified software design | |
| 12 | operating temperature | 0° C. to 55° C. |
| 13 | storage temperature | −20° C. to 60° C. |

Pins of the LCD 12864 are listed as follows.

| PIN NO. | SYMBOL | DESCRIPTION | |
|---|---|---|---|
| 1 | VSS | ground | |
| 2 | VCC | power supply | electrically connected to +3.3 V |
| 3 | V0 | negative terminal of | |
| | | contrast adjustment | |
| 4 | RS | control signal | RS = 0 indicates that instruction data is on data |
| | | | line, and RS = 1 indicates that display data is on |
| | | | data line. |
| 5 | R/W | read/write control | data line is readable at high level, data line is |
| | | signal | written at low level |
| 6 | E | Enable signal | performing read-write of data line cooperating |
| | | | with R/W |
| 7~14 | three-state data line | | |
| 15 | PSB | serial/parallel | serial at low level and parallel at high level |
| | | selection | |
| 16 | NC | not connected | |
| 17 | /RESET | reset terminal | active LOW |
| 18 | VOUT | positive terminal of | |
| | | contrast adjustment | |
| 19 | LED_A | positive terminal of | electrically connected to +3.3 V |
| | | back light | |
| 20 | LED_K | positive terminal of | ground |
| | | back light | |

The input unit 720 can include a keyboard. Data and control instruction can be input by the keyboard. The keyboard can include a plurality of keys to control a plurality of switches. Each of the plurality of switches or any combination thereof can be used to realize a specified function. In one embodiment, the keyboard is an independent connection type of keyboard. More specifically, each of the plurality of keys acts as an independent input to data line. In one embodiment, an operating mode of the metal detector 10 can be regulated by the keyboard. For example, the detection frequency of the metal detector 10 can be switched among several frequency ranges and/or continuously switched within one frequency range.

In one embodiment, the metal detector 10 can further include a power supply unit 800. The power supply unit 800 can be electrically connected to the control unit 300, the analog-digital conversion unit 400, and the frequency selection unit 100 respectively.

In one embodiment, the power supply unit 800 can be a DC power supply V1, such as a CA100FI battery produced by CHINA AVIATION LITHIUM BATTERY CO., LTD. In one embodiment, a power supply voltage of the DC power supply V1 is about 3.2 V, which can meet the power supply requirement of the control unit 300. In one embodiment, the DC power supply V1 can directly provide direct current for the frequency selection unit 100, the display unit 710, and the input unit 720. In one embodiment, to power the operational amplifier 110 in the frequency selection unit 100, an output voltage of the CA100FI battery can be boosted to and stabilized at 12 V by the AS1345D chip. In one embodiment, to power the analog-digital conversion unit 400, the output voltage of the CA100FI battery can be firstly boosted to and stabilized at 5.25 V by the AS1345D chip and then reduced to 5 V by the AS1335 chip. In one embodiment, to power the control unit 300, the output voltage of the CA100FI battery can be firstly boosted to and stabilized at 5.25 V by the AS1345D chip and then reduced to 3.3 V by the AS1335 chip.

Referring to FIG. 5, in one embodiment, an output of the power supply unit 800 can be electrically connected to a voltage stabilizing circuit 810. The voltage stabilizing circuit 810 can be further electrically connected to the control unit 300, the analog-digital conversion unit 400, and the frequency selection unit 100 respectively. The voltage stabilizing circuit 810 can include a resistor R19 and a stabilivolt D1 electrically connected in series with each other and the power supply unit 800. The stabilivolt D1 can be further electrically connected in parallel with the control unit 300. The voltage stabilizing circuit 810 is configured to ensure stability of the voltage input to the control unit 300, the analog-digital conversion unit 400, and the frequency selection unit 100.

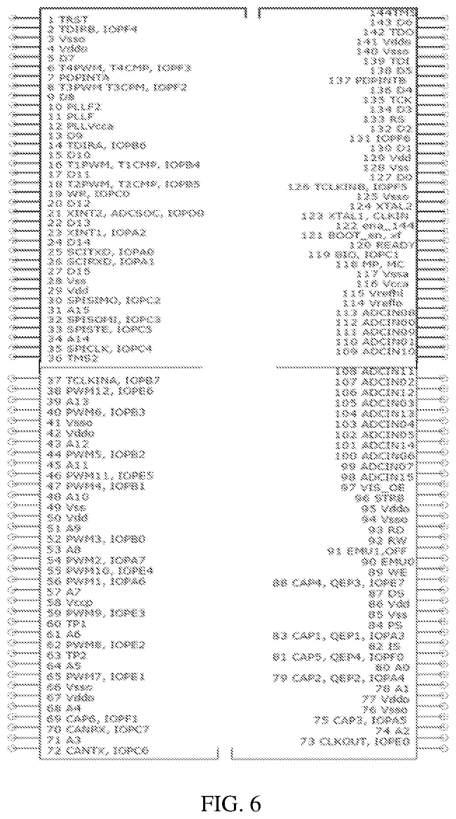

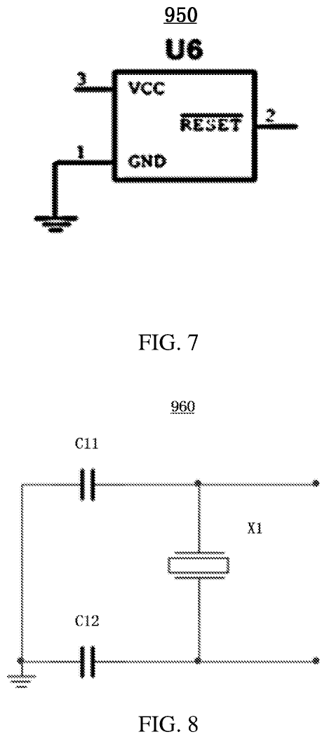

Referring to FIG. 6 to FIG. 8, in one embodiment, the control unit 300 can include a digital signal processor and a reset circuit 950. A VCC interface of the reset circuit 950 can be electrically connected to a power supply. A RESET interface of the reset circuit 950 can be electrically connected to the digital signal processor. The control unit 300 can further include a crystal oscillator circuit 960. An interval of a counter can be set by the crystal oscillator circuit 960. The crystal oscillation circuit 960 can include a capacitor C11, a capacitor C12, and a crystal oscillator X1 which are sequentially electrically connected in series. A wire connecting the capacitor C11 to the capacitor C12 of the crystal oscillation circuit 960 can be grounded.

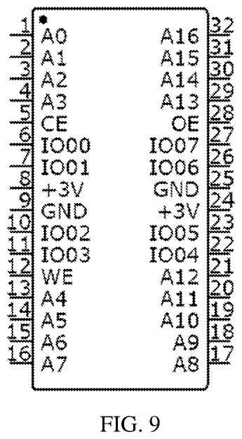

Referring to FIG. 9, in one embodiment, the control unit 300 can further includes an external RAM. The RAM can be CY7C1019. The RAM can be electrically connected to the digital signal processor.

In one embodiment, the analog-digital conversion unit 400 can include an AD7858 chip with 8 input channels and a sampling frequency of up to 200 kHz. The digital signal processor can be provided with DC2289 through SPI serial port. The DC2289 is a 24 bit chip with a sampling frequency of 1 MHz which is 10 times larger than 80 kHz, and the waveform of the received signal can be well described. The AD7858 chip has one control register, one ADC data output register, one status register, one test register, and ten calibration registers. In order to avoid spectral aliasing that occurs after FFT (Fast Fourier Transform), the sampling frequency of the AD7858 chip should be higher than twice of the highest frequency of 80 kHz.

In one embodiment, the received signal is converted by the analog-digital conversion unit 400 to a digitized received signal. Due to the complicated environment, the received signal is not a sinusoidal wave with one frequency, but a signal mixed by different frequencies. Therefore, it is necessary to convert the signal to the frequency domain for frequency analysis to find the main part of the frequency. After receiving the time domain discrete signal converted by the analog-digital conversion unit 400, the FFT is used to convert the signal to the frequency domain. Since the previous analog-digital conversion has a sufficiently high sampling frequency, there will be no aliasing caused by the FFT.

Assuming that the transmitting frequency is f, a data length processed by the FFT is 1, and the sampling frequency is F, then a position of a sample dot of discrete Fourier transform (DFT) n corresponding to the transmitting frequency can satisfy the following equation:

nF=lf

The transmitting signal and the received signal can be respectively analyzed by FFT to obtain digital information of dominant frequencies thereof, and the difference of the phases therebetween and the difference of the intensities therebetween can be determined. Whether the pipeline 500 is corroded can be determined according to the difference of the intensities or the phases.

In one embodiment, the metal detector 10 can further include a third amplifying circuit electrically connected between each of the two receiving coils 500 and the analog-digital conversion unit 400 to amplify the reflected signal.

It will be understood that when an element is referred to as being “connected” or “coupled” to another element, it can be directly connected or coupled to the other element or intervening elements may be present. In contrast, if an element is referred to as being “directly connected” or “directly coupled” to another element, there are no intervening elements present. The terms “vertical”, “horizontal”, “left” and “right” and other similar expressions used herein is for the purpose of describing particular embodiments only and is not intended to be limiting of the invention.

Finally, it is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

What is claimed is:

1. A metal detector for buried and corroded pipeline, comprising:
a transmitting coil configured to transmit a detection signal to a pipeline;
a frequency selection unit electrically connected to the transmitting coil for regulating a frequency of the detection signal;
two receiving coils respectively and symmetrically disposed at two opposite sides of the transmitting coil for respectively receiving a reflected signal returned from the pipeline;
an analog-digital conversion unit respectively and electrically connected to the two receiving coils for converting the reflected signal into a digital signal; and
a control unit electrically connected to the analog-digital conversion unit.

2. The metal detector of claim 1, wherein the transmitting coil and the two receiving coils are planar coils, and vertical lines of the transmitting coil and the two receiving coils are parallel to each other.

3. The metal detector of claim 1, wherein the transmitting coil and the two receiving coils are located in a same plane.

4. The metal detector of claim 1, wherein the two receiving coils are circular, and an outer diameter of each of the two receiving coils is equal to or smaller than a diameter of the pipeline.

5. The metal detector of claim 1, wherein the frequency selection unit comprises:
an operational amplifier;
a first amplifying circuit comprising:
a resistor R4, two ends of the resistor R4 being respectively and electrically connected to an inverting input of the operational amplifier and an output of the operational amplifier; and
a resistor R1, one end of the resistor R1 being grounded and the other end of the resistor R1 being electrically connected to the inverting input of the operational amplifier; and
a frequency selection circuit comprising:
a variable capacitor C1 and a variable resistor R2, one end of the variable capacitor C1 being electrically connected to one end of the variable resistor R2 and grounded, and the other end of variable capacitor C1 and the other end of the variable resistor R2 being electrically connected to a non-inverting input of the operational amplifier;
a variable capacitor C2 and a variable resistor R3 being electrically connected in series between the inverting input of the operational amplifier and the output of the operational amplifier.

6. The metal detector of claim 1, wherein the frequency selection unit further comprises a stabilivolt Dz configured to control an amplitude of a feedback voltage of the operational amplifier, the stabilivolt Dz is electrically connected between the inverting input of the operational amplifier and the output of the operational amplifier.

7. The metal detector of claim 1, further comprising a second amplifying circuit electrically connected between the frequency selection unit and the transmitting circuit, wherein the second amplifying circuit comprises:
a first step-up transformer comprising:
a first primary coil electrically connected to the frequency selection unit;
a first secondary coil and a second secondary coil being electrically connected in series;
a second step-up transformer comprising:
a second primary coil and a third primary coil being electrically connected in series;
a third secondary coil;
a first transistor, one end of the first secondary coil being electrically connected to a base of the first transistor, the other end of the first secondary coil being grounded, an emitter of the first transistor being grounded, a collector of the first transistor being electrically connected to one end of the second primary coil, and the other end of the second primary coil being electrically connected to a cathode of a power supply V1; and
a second transistor, one end of the second secondary coil being electrically connected to a base of the second transistor, the other end of the second secondary coil being grounded, an emitter of the second transistor being grounded, a collector of the second transistor being electrically connected to one end of the third primary coil, and the other end of the third primary coil is electrically connected to the cathode of the power supply V1.

8. The metal detector of claim 1, further comprising:
a human-machine interaction module comprising a display unit and an input unit respectively and electrically connected to the control unit.

9. The metal detector of claim 1, further comprising:
a power supply unit respectively and electrically connected to the control unit, the analog-digital conversion unit, and the frequency selection unit.

10. The metal detector of claim 1, further comprising:
a voltage stabilizing circuit electrically connected to an output of the power supply unit and further respectively and electrically connected to the control unit, the analog-digital conversion unit, and the frequency selection unit, wherein the voltage stabilizing circuit comprises:
a resistor R19 and a stabilivolt D1, the resistor R19, the stabilivolt D1, and the power supply unit being electrically connected in series, and the stabilivolt D1 being electrically connected in parallel with the control unit.

11. The metal detector of claim 1, wherein the frequency selection unit is configured to regulate the frequency of the detection signal within a range from about 20 kHz to about 80 kHz.

12. The metal detector of claim 1, wherein the frequency selection unit is configured to regulate the frequency of the detection signal corresponding to an optimal detection frequency of at least one of Fe₂O₃, FeOOH, FeO, Fe(OH)₂, and Fe₃O₄.

13. The metal detector of claim 5, wherein a ratio of a resistor value of the resistor R4 to a resistor value of the resistor R1 is slightly more than 2.

14. The metal detector of claim 1, wherein the analog-digital conversion unit has a sampling frequency of more than 160 kHz.

15. A metal detector for buried and corroded pipeline, comprising:
a transmitting coil configured to transmit a detection signal to a pipeline;
a frequency selection unit electrically connected to the transmitting coil for regulating a current frequency of the transmitting coil;
two receiving coils respectively and symmetrically disposed at two opposite sides of the transmitting coil for respectively receiving a reflected signal returned from the pipeline;
a signal processing unit respectively and electrically connected to the two receiving coils for calculating an intensity of the reflected signal of each of the two receiving coils.

16. The metal detector of the claim 15, wherein the transmitting coil and the two receiving coils are planar coils, and vertical lines of the transmitting coil and the two receiving coils are parallel to each other.

17. The metal detector of claim 15, wherein the transmitting coil and the two receiving coils are located in a same plane.

18. The metal detector of claim 15, wherein the two receiving coils are circular, and an outer diameter of each of the two receiving coils is equal to or smaller than a diameter of the pipeline.

19. The metal detector of claim 15, wherein the transmitting coil and the two receiving coils are fixed on a frame.

20. The metal detector of claim 15, wherein the signal processing unit comprises:
an analog-digital converter respectively electrically connected to the two receiving coils; and
a digital signal processor electrically connected to the analog-digital converter.
